(19) United States
(12) Patent Application Publication
(10) Pub. No.: US 2026/0047717 A1
(43) Pub. Date: Feb. 19, 2026

(54) CERAMIC COATED FOODWARE AND COOKWARE

(71) Applicant: Meyer Intellectual Properties Limited, Kowloon (HK)

(72) Inventor: Stanley Kin Sui Cheng, Hillsborough, CA (US)

(73) Assignee: Meyer Intellectual Properties Limited, Kowloon (HK)

(21) Appl. No.: 19/298,747

(22) Filed: Aug. 13, 2025

Related U.S. Application Data
(60) Provisional application No. 63/682,600, filed on Aug. 13, 2024.

(51) Int. Cl. A47J 36/02; C23C 4/08; C23C 14/06; C23C 28/00

(52) U.S. Cl. CPC A47J 36/02; C23C 14/0641; C23C 28/321; C23C 28/34; C23C 4/08

(57) ABSTRACT

According to one example, a method includes forming at least a surface layer of a metal substrate from an alloy of copper that has a hardness of at least about 150 Vickers Hardness (HV), and applying by a physical vapor deposition (PVD) process, one or more layers of a ceramic coating on the outer surface layer.

### CROSS REFERENCE TO RELATED APPLICATIONS

This application claims the benefit of priority to U.S. Provisional Patent Application No. 63/682,600 filed on Aug. 13, 2024, the entirety of which is incorporated herein by reference.

### TECHNICAL FIELD

This disclosure relates generally to foodware (e.g., item(s) used for containing, serving, or consuming prepared food, including cookware), and cookware (e.g., items used for cooking, such as pots, pans, and baking dishes). This disclosure more specifically relates to foodware and cookware items having thin film ceramic coating(s), particularly Physical Vapor Deposition (PVD) coating(s) of metal compounds of oxygen, nitrogen and/or carbon, and combinations thereof.

### BACKGROUND

Prior methods of coating metallic cookware have been largely limited to specific metals, notably steel and related ferrous alloys. However, stainless steel has poor thermal conductivity, so it uses in cookware is primarily as a cladding or where thermal conductivity is not important to the end use application.

U.S. Pat. No. 8,021,768, which is incorporated herein by reference in its entirety, teaches that non-ferrous materials like copper and aluminum are soft and porous and that corrosion is major concern with these materials. It further discloses that such substrates require a thick, dense, and smooth base coating deposited on the substrate before a PVD layer can be deposited by Cathodic arc deposition.

U.S. Pat. No. 8,021,768 further teaches that the deficiencies with copper and aluminum substrates, as used in foodware/cookware applications, can be overcome by first depositing a base coating on a first surface of the metal substrate using a combination of cathodic arc and sputtering processes. Sputtering processes may be better than cathodic arc processes in terms of providing good corrosion resistance, as sputtering processes, (e.g., including, but not limited to, DC sputtering, reactive sputtering, or magnetron sputtering) can be precisely controlled by the defined coating parameters, such as bias voltage and suitable device, to produce a smooth, dense film. Such a co-deposited bonding layer comprises a material selected from metals, alloys of metals, or combinations thereof. A further rational is that the cathodic arc generates macro-particles, so-called droplets, which can interrupt a dense film, resulting in inferior corrosion resistance. U.S. Pat. No. 8,021,768 also teaches that the combination is favored because the cathodic arc process bombards the substrate with high energy metal ions that can penetrate into the substrate, resulting in good strength of adhesion of the base layer to the substrate.

However, sputtering processes are relatively slow compared to cathodic arc deposition, and thus considerably increase the cycle time of the vacuum coating process. Furthermore, in some examples, for this process, the coating chamber is equipped with both (i) sputtering sources and a sputtering power supplier, and (ii) cathodic arc sources and the associated power supplies. This not only increases the chamber capital costs but eliminates space on the chamber walls that might be used to place additional cathodic arc sources to reduce the coating cycle time (e.g., which can reduce operating costs). While U.S. Pat. No. 8,021,768 teaches that separate chambers can be used for each process, (e.g., a first chamber for co-deposition of some metal by sputtering, and a second chamber for cathodic arc deposition), this increases capital costs and the operating expenses of handling multiple parts, and placing and removing them from two chambers rather than one.

While there are now improved sputtering methods that can deposit hard or ceramic metal compounds similar in properties to such compounds deposited by cathodic arc deposition, U.S. Pat. No. 8,021,768 teaches in essence that the combination of selected metals that are co-deposited produces a harder, denser well adhered layer that is harder than the aluminum or copper of the foodware/cookware articles, and is thus ready to receive a multi-layer coating of ceramic materials.

While stainless steel alloys can be directly coated with ceramic metal compounds, cladding aluminum or copper with stainless steel on both sides is an expensive process. The stainless steel is generally thicker than about 0.8 mm, and due to its own lower thermal conductivity (e.g., lower than copper or aluminum), it tends to slow the transfer of heat to the pan ingredients.

### SUMMARY

In some examples, the present disclosure provides a process for forming various foodware or cookware articles from rolled sheet stock of aluminum, copper, and alloys thereof, that can be directly coated with ceramic metal compounds, to provide for sealing of the base metal used to form the foodware or cookware articles, as well impart outer layers that improve the scratch, staining, and corrosion resistance of the foodware or cookware articles.

In some examples, high hardness copper alloys can be formed into foodware or cookware articles, and then coated with ceramic compounds using a PVD process. In some examples, the coating remains durable and resistant to thermal cycling without an intervening metal layer that is deposited by a combination of sputtering metal and cathodic arc deposition.

In some examples, the present disclosure provides a copper cookware article comprising a copper substrate with at least an outer surface layer formed from an alloy of copper that has a hardness of at least about 150 Vickers Hardness (HV) and one or more layers of a metal ceramic coating applied by a PVD process on the outer surface layer.

In some examples, the copper substrate consists essentially of an alloy of copper with a thermal conductivity of at least about 260 W/(m-K). In some examples, the alloy of copper has become hardened by precipitates of alloying elements prior to the PVD process. In some examples, the copper substrate contains non-copper metals and metalloids that total less than 3 wt. %. In some examples, the copper substrate contains non-copper metals and metalloids that total more than about 0.5 wt. %.

In some examples, the copper substrate has at least one outer layer (e.g., an outer cladding layer) on an inner layer, in which the inner layer is more ductile than the outer layer. In some examples, the inner layer is more thermally conductive than the outer layer. In some examples, the outer layer is formed by a thermal spray process on a metal substrate. In some examples, the outer layer is formed by a thermal spray process on the metal substrate after the metal substrate is deep drawn to form a cookware vessel from a planar sheet. In some examples, the metal substrate is selected from the group consisting of copper, aluminum and alloys thereof.

### BRIEF DESCRIPTION OF THE FIGURES

For a more complete understanding of the present disclosure and one or more examples of the features and advantages of the present disclosure, reference is now made to the following description, taken in conjunction with the accompanying drawings, in which:

FIG. 1 is a cross-section view of a prior art PVD coated copper cookware article.

FIG. 2 is a cross-section of a prior art stainless steel clad aluminum or copper cookware sheet, used to form a cookware article.

FIG. 3 is a cross-section view of an example foodware or cookware article 200 according to one example of the present disclosure.

FIG. 4 is a cross-section view of an example foodware or cookware article 200 according to one example of the present disclosure.

### DETAILED DESCRIPTION

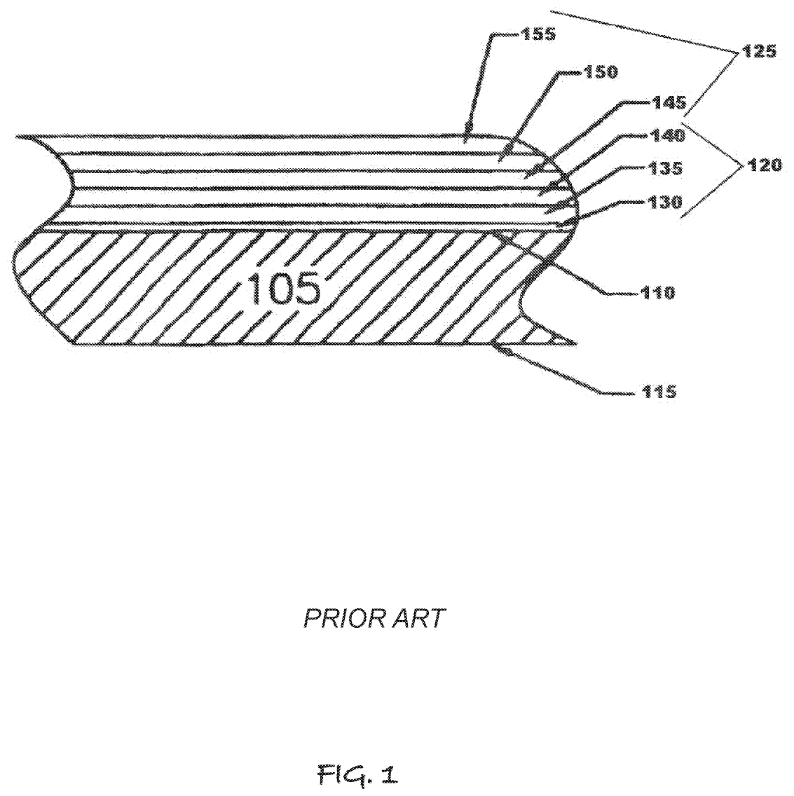

Embodiments of the present disclosure are best understood by referring to FIGS. 1-4 of the drawings, like numerals being used for like and corresponding parts of the various drawings.

FIG. 1 is a cross-section view of a prior art cookware article disclosed in U.S. Pat. No. 8,021,768. In the illustrated example, the cookware article includes a stainless steel substrate or outer layer that is coated with ceramic metal compounds by a PVD process. The substrate is designated 105 (and includes first surface 110 and second surface 115), and the PVD coating is designated as layers 130, 135, 140, 145, 150 and 155, divided into groups 120 and 125.

In FIG. 1, a base coating 120 is deposited on the first surface 110 of the substrate 105, and a ceramic coating 125 is deposited adjacent to the base coating 120. The total thickness of the base coating 120 is typically between about 2 and about 20 microns, while the total thickness of the ceramic coating 125 is generally between about 1 to about 20 microns.

The base coating 120 includes a combination cathodic arc and sputtered bonding layer 130. Also, the base coating 120 includes a sputtered layer 135, which is deposited by a sputtering process adjacent to the combination cathodic arc and sputtered bonding layer 130. The base coating 120 further includes a second combination cathodic arc and sputtered bonding layer 140 deposited adjacent to the sputtered layer 135.

The ceramic coating 125 includes a first (Ti,Al,Cr)N layer 145 (e.g., a PVD nitride or carbonitride layer) that is deposited adjacent to the base coating 120. There can optionally be a first layer of chromium nitride 150 deposited adjacent to the first (Ti,Al,Cr)N layer 145. Although the first chromium nitride layer 150 is shown as being deposited on the first (Ti,Al,Cr)N layer 145 in this example, there could be one or more intervening layers between the first (Ti, Al,Cr)N layer 145 and the first chromium nitride layer 150, if desired. The first chromium nitride layer 150 is generally less than about 2 microns thick. In the event the upper layers are penetrated, the first chromium nitride layer 150 provides corrosion resistance and oxidation resistance. A second layer of (Ti,Al,Cr)N 155 can optionally be deposited on the first chromium nitride layer 150. The second (Ti,Al,Cr)N layer 155 is generally less than about 10 microns thick.

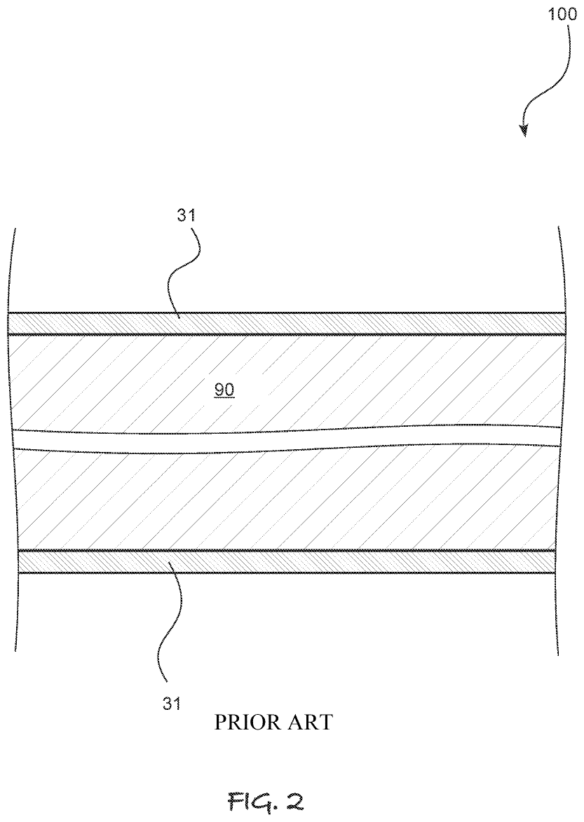

FIG. 2 is a cross-section view of a prior art foodware or cookware article 100 having a metal substrate or core 90. The core 90 is covered on the inside and outside by stainless steel cladding layers 31, such as highly thermally conductive aluminum or copper. The stainless steel cladding layers 31 are typically about 0.8 mm to about 1.5 mm thick.

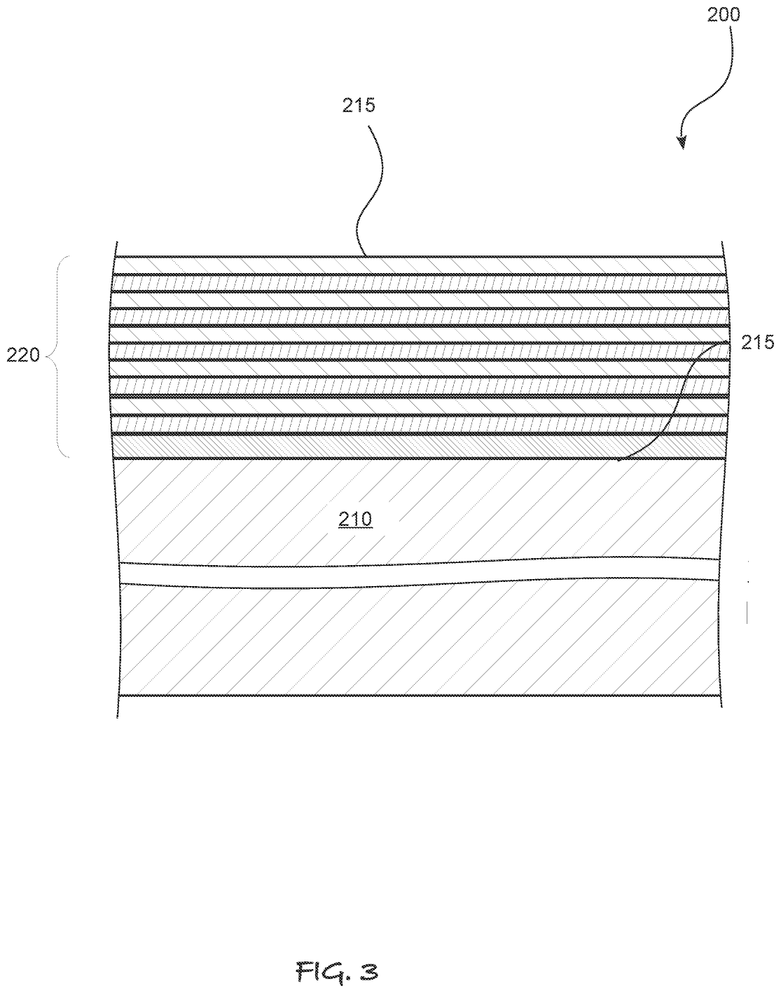

FIG. 3 is a cross-section view of an example foodware or cookware article 200 according to one example of the present disclosure.

In the example illustrated in FIG. 3, the foodware or cookware article 200 includes a substrate 210, and a ceramic coating 220 (e.g., PVD coating) deposited on an upper outer surface 215 of the substrate 210.

In some examples, the substrate 210 is a high thermal conductivity alloy with a high hardness and/or modulus of elasticity. In some examples, the substrate 210 is ductile enough for the plastic deformation of deep drawings, yet hard enough (after the drawing) to, in some examples, not require a thick intermediate layer (deposited by a combination of sputtering and cathodic arc deposition, an example of which is base coating 120 of FIG. 1) between the substrate 210 and the ceramic coating 220

While all metals harden from the process of deep drawing (to some extent), a foodware or cookware vessel will traditionally have a gradient of work hardened material in some portions of the vessel but not in others. For example, the flat bottom of the vessel undergoes little deformation, the upper wall of the vessel undergoes more deformation, and the transition from the perimeter of the bottom to the upright wall of the vessel undergoes the most deformation.

There are significant challenges in alloying different material combinations to obtain a high thermal conductivity (e.g., a thermal conductivity that is greater than about 150 W/m-K). For example, while pure metals have high thermal conductivity, the process of alloying introduces an “impurity” that scatters photons to reduce thermal conductivity.

It has been discovered that a limited number of alloys, and preferably copper alloys in some examples, (i) can retain high thermal conductivity, (ii) can still be hardened by alloying and proper heat treatments to be suitable for optimum deep drawing methods to form foodware and cookware, and (iii) after the drawings process, are sufficiently smooth, hard and pore free to be suitable for a receiving a ceramic metal compound coating, such as by a PVD process, but without the need to deposit an intermediate hard metal layer by a combination of sputtering and cathodic arc coating.

In some examples, the thermally conductivity for the substrate 210 is at least about 260 W/(m-K), but more preferably at least about 300 W/(m-K), and most preferably at least about 330 W/(m-K). However, when the alloy is merely a layer on a thicker core of relatively pure copper, the thermal conductivity can be lower, in some examples.

In addition to the above levels of thermal conductivity, in some examples, the substrate 210 has a modulus of elasticity of at least about 100 Gigapascals (GPa), more preferably at least about 130 GPa, and most preferably at least about 150 GPa. In some examples, the substrate 210 has a hardness of preferably at least about 150 HV, more preferably at least about 175 HV, and even more preferably at least about 200 HV.

In accordance with the discovery above, in some examples, the substrate 210 is a copper alloy that is preferably precipitation hardened by a co-alloying with relatively pure copper elements, such as chromium, silicon, chromium, zirconium, silver, tin, magnesium, phosphorus, titanium, iron, cobalt, zinc and beryllium, and the like. In some examples, the addition of these metals and metalloids to the copper is usually less than 2-3 wt. % in total, preferable less than about 1.5 wt. %, but more preferably in the range of between about 1.5 wt. % and 0.5 wt. %, in some examples.

In some examples, the copper alloy of substrate 210 comprises both chromium and zirconium, such as the alloy with the designation C18160 (UNS), which is copper that substantially consists of about 0.8 wt. % chromium and 0.2 wt. % zirconium, and is available from KME Germany GMBH (Osnabrück, Germany). KME reports that rolled sheets under the designation STOL-95 alloy have a minimum elongation of 2% to 8%, depending on aging and temper. The sheets of the STOL-95 alloy are preferably obtained from the rolling mill as soon as possible after casting the alloy and rolling, in some examples, so that the elongation to break is higher, before precipitates of the alloying elements can form, which increases hardness but reduces elongation.

In other examples, the copper alloy of substrate 210 is a copper alloy with the designation C18150 (UNS), which is copper that substantially consists of about 0.5 to 1.5 wt. % chromium and about 0.2 wt. % zirconium, as well as the coatings on top of essential pure very ductile copper 90, examples of which are described below.

In some examples, these copper alloys (and other suitable alloys) have (i) increased modulus of elasticity, and (ii) increased hardness with minimal (in some examples) loss of thermal conductivity by any combination of work hardening (e.g., from rolling into sheets, and deep drawing, or similar mechanical deformation, to at least the surface to be coated, and the formation of solid precipitates of the metal and metalloid components that are added to copper (or other metal) to form the alloy). As the kinetics of the formation of precipitates varies with rate of cooling after casting from the molten state, and the total strain from hot of cold rolling, a sheet of copper can be formed or obtained having a suitable thickness (e.g., 1 to 5 mm) for forming foodware and cookware while still being relatively ductile to provide for facile deep drawing without tearing, forming orange peel surface, or undergoing other defects.

In some examples, the alloy for the substrate 210 (e.g., the copper alloy(s) discussed above) are rolled to a desired foodware and/or cookware thickness after casting and provided to the manufacturer for deep drawings. In some examples, this rolling is performed promptly (e.g., without aging that would induce the formation of precipitates of the alloying elements in the copper matrix, thus increasing hardness, and lowering ductility), in some examples. In some examples, after deep drawing, sheets that are under aged, or that are not fully precipitation hardened sheets, can be further processed, if desired, to accelerate the precipitation hardening mechanism by heat treating, or by deep drawing at elevated temperatures. Deep drawing of any hardened sheets can also be conducted at high temperature to improve ductility, in some examples.

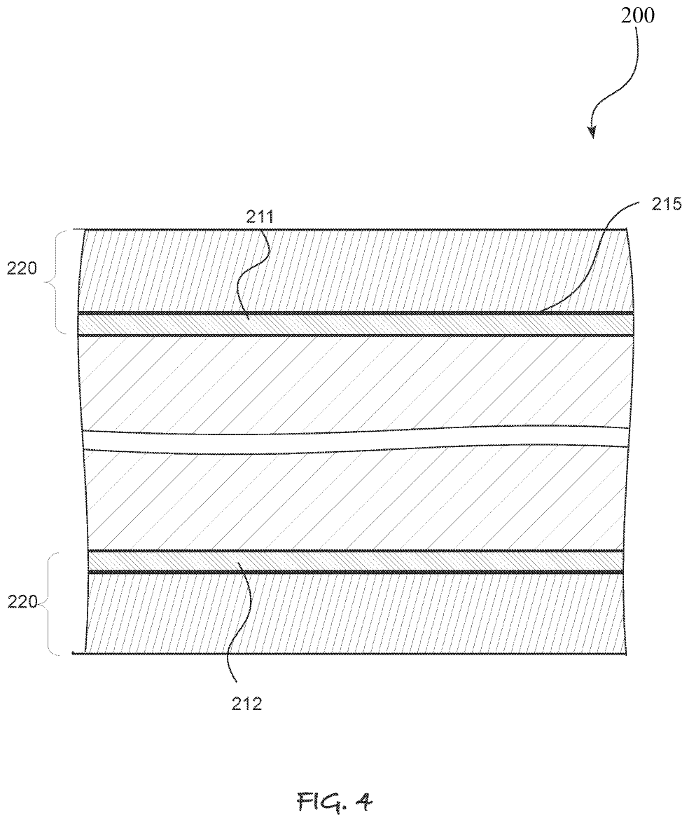

Traditionally, it is not favored to use such precipitation hardened alloys for a substrate for forming a foodware or cookware article 200 because of the resulting low ductility. In some examples, however, these materials (e.g., the alloys discussed above) may not form the entire substrate 210. Instead, in some examples, these materials may only be used as an inner layer 211 (or both an outer 212 layer and inner layer 211, as is seen in FIG. 4) of the substrate 210.

In some examples, the substrate 210 is a metal substrate (e.g., a copper substrate), and the metal substrate includes an inner layer 211 (or both an outer 212 layer and inner layer 211) that is applied to the metal substrate. In such examples, the inner layer 211 and/or outer layer 212 is any of the alloys disclosed herein and the like

In some examples, the inner layer 211 and/or outer layer 212 may be laminated to a ductile metal sheet (e.g., a copper sheet). In some examples, this can be accomplished by hot or cold rolling, or a combination of hot and cold rolling. The hot rolling is, in some examples, preferably done with outer cladding layers 211 and/or 212 of the preferred and similar copper alloys at temperatures below those where the alloying elements start to precipitate from solution in the copper matrix. Because precipitates tend to harden the surface, and reduce elongation, it is, in some examples, preferable that any heat treating occurs after deep drawing to form the foodware or cookware article 200, and before PVD coating the foodware or cookware article 210. An example of this construction is illustrated from a planar portion of PVD coated cookware in FIG. 4 in which the one or more ceramic layers are designated by reference numeral 220.

In examples, the inner layer 211 and/or outer layer 212 may be applied after the substrate 210 of foodware or cookware article 200 has been deep drawn (e.g., deep drawn from a substantially planar body to form the primarily copper cookware vessel). In such examples, the inner layer 211 and/or outer layer 212 may be applied by any number of additive processes. For example, the inner layer 211 and/or outer layer 212 may be applied using a thermal spray as a powder. Such a thermal spray includes plasma and are spraying (from a wire of the alloy), in some examples. Also, such a thermal spray includes a cold high velocity thermal spray, which produces high density pore free coatings, and also work hardens the substrate 210 (and also work hardens the alloys that are deposited). In some examples, the layers are preferably less than a 1 mm thick, and more preferably less than 0.1 mm thick, and most preferably less than 0.1 mm (100 microns thick) to about 0.01 microns thick (10 microns).

In some examples, thermal spraying that remelts an alloy wire is expected to dissolve the alloying elements in the copper matrix, which on solidification would only slowly again precipitate to harden this added surface. Other processes of additive deposition are known which, like high velocity cold spray, produce coatings that are well adhered to the substrate but generally free of pores. A porosity in the additive coating of the alloy can, in some examples, interfere with the ceramic coating 220 by being a source of outgassing during the deposition process.

In some examples, the foodware or cookware article 200 can have such an outer layer that is formed by a thermal spray process on the substrate 210 after the substrate 210 is deep drawn to form the foodware or cookware article 200 from a planar sheet. In some examples, the substrate 210 of such a foodware or cookware article 200 can be copper, aluminum, and alloys thereof.

In some examples, (a) the composition of the substrate 210 (or the inner layer 211 and/or the outer layer 212 of the substrate 210), (b) the composition of the ceramic coating 220 (e.g., which can be applied over the preferred copper alloys), and/or (c) the composition of a cladding provided over a more ductile or purer form of copper (which would have higher thermal conductivity), is not limited to the alloys discussed above. In some examples, (a) the composition of the substrate 210 (or the inner layer 211 and/or the outer layer 212 of the substrate 210), (b) the composition of the ceramic coating 220 (e.g., which can be applied over the preferred copper alloys), and/or (c) the composition of a cladding provided over a more ductile or purer form of copper (which would have higher thermal conductivity), includes those disclosed in (i) U.S. Pat. No. 6,906,295 (issued to GE on Jun. 14, 2005); (ii) U.S. Pat. No. 6,942,935 (issued to GE on Sep. 13, 2005); (iii) U.S. Pat. No. 7,462,375 (issued to GE on Dec. 9, 2008); and U.S. Pat. No. 8,021,768 (issued on Sep. 20, 2011) (which discloses compositions deposited on intermediate layers that were deposited via co-sputtering and co-cathodic arc). All of these patents are incorporated herein in their entirety.

In some examples, (a) the composition of the substrate 210 (or the inner layer 211 and/or the outer layer 212 of the substrate 210), (b) the composition of the ceramic coating 220 (e.g., which can be applied over the preferred copper alloys), and/or (c) the composition of a cladding provided over a more ductile or purer form of copper (which would have higher thermal conductivity), additionally includes Zirconium Nitride. Examples of such compositions are disclosed in (i) U.S. Pat. No. 6,360,423, entitled “Stick resistant coating for cookware” (issued to Groll, W. A. on March 26); and (ii) U.S. Pat. No. 7,093,340, entitled “Stick resistant ceramic coating for cookware” (issued to Groll, W. A. on Aug. 22, 2006). All of these patents are incorporated herein in their entirety.

In some examples, (a) the composition of the substrate 210 (or the inner layer 211 and/or the outer layer 212 of the substrate 210), (b) the composition of the ceramic coating 220 (e.g., which can be applied over the preferred copper alloys), and/or (c) the composition of a cladding provided over a more ductile or purer form of copper (which would have higher thermal conductivity), additionally includes those disclosed in U.S. Patent Pub. No. 2014/0311358, entitled “Stain-Resistant Cooking Surface and Cookware Item or Electrical Household Appliance Comprising such a Cooking Surface”, and which is also incorporated herein in its entirety. U.S. Patent Pub. No. 2014/0311358 describes mixed coatings or alloys of ceramic such as an (X,Al)N-type coating—which is a coating of nitride(s) of the one or more X transition metal(s), enriched with aluminum, in which niobium and/or zirconium make(s) up the majority of the X transition metal(s). This can include a coating comprising only one nitride (e.g., a mixed nitride of Zr and Nb enriched with aluminum), or several nitrides (e.g., a nitride of Zr or of Nb making up the majority and a nitride of Ti or of Cr making up the minority, these nitrides being enriched with aluminum), in some examples.

In some examples, the ceramic coating 220 (which is, for example, deposited on the copper alloys disclosed herein, and equivalents thereto) has one or more layers that are optionally an oxide, oxynitride, oxynitrocarbide, oxycarbide, as well as a nitride or carbonitride. In some examples, such compounds may have a composition of MeOxNyCz, in which “Me” is a metal; “x” is zero or greater than zero; “y” is zero or greater than zero; “z” is zero or greater than zero, and the sum of “x”, “y”, and “x” (i.e., x+y+z) is generally close to one or greater than one. In some non-limiting examples, the Me is a single metal, or a combination of metals. In some examples, the Me is any transition metal.

In some examples, the ceramic coating 220 (e.g., ceramic metal coating) is deposited by a PVD process, such as a PVD process selected from sputtering, reactive sputtering, magnetron sputtering, and a cathodic arc deposition process. The ceramic coating 220 is shown as multiple layers with different hatching in FIG. 3, but as a monolithic material in FIG. 4. These illustrations are not intended to limit the ceramic metal coating 220 to a single layer in the embodiment in FIG. 4, or to the exact number of discrete layers illustrated in FIG. 3. Also, the ceramic coating 220 may be on the inside of the foodware or cookware article 200, the outside of the foodware or cookware article 200, or on both the inside and the outside of foodware or cookware article 200.

In some examples, the thickness of the ceramic coating 220 is preferably in a range of about 1.0 to about 20 microns. In some examples, the surface 215 of the substrate 210 has a surface finish of less than about 20 micro-inches after forming the foodware or cookware body by deep drawing, and before PVD deposition of the ceramic coating 220. In some examples, the outer surface 215 of the ceramic coating 220 preferably has a surface finish of less than about 20 micro-inches (e.g., achieved by polishing the ceramic coating 220 after the PVD deposition process of the ceramic coating 220). Any polishing methods, including electro-polishing, may be utilized. In some examples, the outer surface 215 of the metal coating 220 has a surface finish of less than about 4 micro-inches (e.g., achieved by polishing the ceramic coating 220 after the PVD deposition process of the ceramic coating 220).

The durability of the ceramic coating 220 (which was PVD deposited on the preferred copper alloy substate 210) was comparatively tested against a rather pure and higher thermal conductivity grade of cookware used conventionally in forming cookware. It was discovered that the preferred alloy (e.g., the preferred copper alloy) withstood over 100,000 abrasion cycles, while the conventional copper alloy did not.

This specification has been written with reference to various non-limiting and non-exhaustive embodiments or examples. However, it will be recognized by persons having ordinary skill in the art that various substitutions, modifications, or combinations of any of the disclosed embodiments or examples (or portions thereof) may be made within the scope of this specification. Thus, it is contemplated and understood that this specification supports additional embodiments or examples not expressly set forth in this specification. Such embodiments or examples may be obtained, for example, by combining, modifying, or reorganizing any of the disclosed components, elements, features, aspects, characteristics, limitations, and the like, of the various non-limiting and non-exhaustive embodiments or examples described in this specification.

What is claimed is:

1. A foodware or cookware article comprising:
a metal substrate with at least a surface layer formed from an alloy of copper that has a hardness of at least about 150 Vickers Hardness (HV); and
one or more layers of a ceramic coating applied by a physical vapor deposition (PVD) process on the surface layer.

2. The foodware or cookware article of claim 1, wherein the alloy of copper has a thermal conductivity of at least about 260 W/(m-K).

3. The foodware or cookware article of claim 1, wherein the alloy of copper has become hardened by precipitates of alloying elements prior to the PVD process.

4. The foodware or cookware article of claim 1, wherein the metal substrate is formed entirely from the alloy of copper.

5. The foodware or cookware article of claim 1, wherein only the surface layer of the metal substrate is formed from the alloy of copper.

6. The foodware or cookware article of claim 1, wherein the metal substrate comprises at least one outer cladding layer on an inner layer, wherein the inner layer is more ductile than the at least one outer cladding layer.

7. The foodware or cookware article of claim 6, wherein the inner layer is more thermally conductive than the at least one outer cladding layer.

8. The foodware or cookware article of claim 1, wherein the metal substrate contains non-copper metals and metalloids that total less than 3 wt. %.

9. The foodware or cookware article of claim 1, wherein the metal substrate contains non-copper metals and metalloids that total more than about 0.5 wt. %.

10. The foodware or cookware article of claim 1, wherein the surface layer is formed by a thermal spray process on the metal substrate.

11. The foodware or cookware article of claim 1, wherein the surface layer is formed by a thermal spray process on the metal substrate after the metal substrate is deep drawn to form a shape of the foodware or cookware article from a planar sheet.

12. The foodware or cookware article of claim 1, wherein the metal substrate is selected from the group consisting of copper, aluminum, and alloys thereof.

13. A method, comprising:
forming at least a surface layer of a metal substrate from an alloy of copper that has a hardness of at least about 150 Vickers Hardness (HV); and
applying, by a physical vapor deposition (PVD) process, one or more layers of a ceramic coating on the outer surface layer.

14. The method of claim 13, wherein the alloy of copper has a thermal conductivity of at least about 260 W/(m-K).

15. The method of claim 13, wherein forming the at least the outer surface layer of the metal substrate from the alloy of copper comprises forming the entire metal substrate from the alloy of copper.

16. The method of claim 13, wherein forming the at least the outer surface layer of the metal substrate from the alloy of copper comprises forming only the surface layer from the metal substrate of the alloy of copper.

17. The method of claim 13, wherein forming the at least the outer surface layer of the metal substrate from the alloy of copper comprises using a thermal spray process to spray the outer surface layer on the metal substrate.

18. The method of claim 13, wherein forming the at least the outer surface layer of the metal substrate from the alloy of copper comprises using a thermal spray process to spray the outer surface layer on the metal substrate after the metal substrate is deep drawn to form a shape of a foodware or cookware article from a planar sheet.

19. The method of claim 13, wherein forming the at least the outer surface layer of the metal substrate from the alloy of copper comprises applying the outer surface layer on the metal substrate before the metal substrate is deep drawn to form a shape of a foodware or cookware article from a planar sheet.

20. The method of claim 13, wherein the PVD process is selected from a group consisting of sputtering, reactive sputtering, magnetron sputtering, and a cathodic arc deposition process.
